(19) United States
(12) Patent Application Publication
(10) Pub. No.: US 2012/0003783 A1
(43) Pub. Date: Jan. 5, 2012

(54) LEAD FOIL LOOP FORMATION

(76) Inventor: Richard S. Malik, JR., Rossford, OH (US)

(21) Appl. No.: 13/170,759

(22) Filed: Jun. 28, 2011

Related U.S. Application Data
(60) Provisional application No. 61/360,192, filed on Jun. 30, 2010.

(51) Int. Cl. H01L 31/18; B21D 5/08; B21D 33/00

(52) U.S. Cl. 438/73; 72/252.5; 29/17.2; 257/E31.001

(57) ABSTRACT

A lead foil loop formation tool includes a pair of rollers.

### TECHNICAL FIELD

This invention relates to a lead foil loop formation tool for photovoltaic module manufacture. The lead foil loop formation tool includes a pair of rollers

### BACKGROUND

Lead foil and other conductive strips are widely used in electrically connecting photovoltaic modules. In photovoltaic module manufacturing process, the lead foil operation procedure includes the step of forming a lead foil loop before attaching the back cover to the module.

### DESCRIPTION OF DRAWINGS

FIG. 1 illustrates a lead foil loop forming procedure.

FIG. 2 illustrates a lead foil loop forming procedure and a pair of loop formation rollers.

FIG. 3 illustrates a lead foil loop and a back cover.

FIG. 4 illustrates a top view of a photovoltaic module with a lead foil loop and a back cover.

FIG. 5 illustrates a side view of a photovoltaic module with a lead foil loop and a back cover.

FIG. 5A illustrates a magnified view of part A in FIG. 5.

### DETAILED DESCRIPTION

A photovoltaic module can include a plurality of photovoltaic devices or photovoltaic cells formed on a substrate. Each photovoltaic cell can include a transparent conductive layer formed adjacent to a substrate, a semiconductor window layer adjacent to the transparent conductive layer, and a semiconductor absorber layer adjacent to the semiconductor window layer. Each photovoltaic cell can include a back contact adjacent to the semiconductor absorber layer. The photovoltaic cell back contacts of the plurality of photovoltaic cells can be electrically connected by any suitable configuration of electrical conductors (including, for example, two lead foils) to electrically connect the photovoltaic cells to at least one positive bus and one negative bus.

Lead foils can be positioned and formed into a loop before the back cover is positioned on the module. The lead foil loop can be positioned through a hole of the back cover. However, the formed loop may not be perpendicular to the surface of the plate and may cover a footprint sufficiently large to complicate threading the lead foil loop through the back cover hole. The lead foil loop can be covered by the back cover resulting in either rework or scrap. A lead foil loop formation tool and related method for photovoltaic module manufacture are developed to address this problem.

In one aspect, a method of forming lead foil loop for photovoltaic module manufacture can include positioning a lead foil adjacent to a photovoltaic module surface and pulling a portion of lead foil up. The method can include forming a lead foil loop by pushing a pair of loop formation rollers together against the portion of lead foil from opposite directions. The first roller in the pair can include a circumferential indentation and the second roller can include a corresponding circumferential protuberance. The indentation can interlock with the protuberance to form a rib in the length of the lead foil loop when the rollers come together with a lead foil loop in between.

The method can include positioning a back cover adjacent to the photovoltaic module surface. The back cover can have a hole and the lead foil loop can be positioned through the back cover hole. The ribbed lead foil loop can be more perpendicular to the back cover hole compared to an unribbed lead foil loop. The ribbed lead foil loop can have a smaller footprint than an unribbed lead foil loop. The lead foil can include a tin plated copper foil. The lead foil can include an adhesive backing.

In another aspect, a method of forming lead foil loop for photovoltaic module manufacture can include positioning a first lead foil adjacent to a photovoltaic module surface, pulling an end portion of the first lead foil up, positioning a second lead foil adjacent to a photovoltaic module surface, and pulling an end portion of the second lead foil up. The pull-up end portions of the first lead foil and the second lead foil can be opposite to each other. The method can include forming a lead foil loop by pushing a pair of loop formation rollers together against the pull-up lead foil end portions from opposite directions and attaching the end portions together. The first roller of the pair can include a circumferential indentation. The second roller can include a corresponding circumferential protuberance. The indentation can interlock with the protuberance to form a rib in the length of the lead foil loop when the rollers come together with a lead foil loop in between.

The method can include positioning a back cover adjacent to the photovoltaic module surface. The back cover can have a hole and the lead foil loop can be positioned through the back cover hole. The ribbed lead foil loop can be more perpendicular to the back cover hole compared to an unribbed lead foil loop. The ribbed lead foil loop can include a smaller footprint than an unribbed lead foil loop.

In another aspect, a lead foil forming tool can include a pair of loop formation rollers. The first roller of the pair can include a circumferential indentation and the second roller can include a corresponding circumferential protuberance. The indentation can interlock with the protuberance to form a rib in the length of a lead foil loop when the rollers come together with a lead foil loop in between.

The loop formation rollers can include a polymer. The loop formation rollers can include a metal. The first roller can have a diameter between 0.3 cm and 5 cm. The second roller can have a diameter between 0.3 cm and 5 cm. The circumferential protuberance can include an o-ring positioned around the first roller. The circumferential protuberance can include a molded feature on the first roller. The circumferential protuberance can include a machined feature on the first roller.

In another aspect, a method of manufacturing a photovoltaic module can include forming a plurality of photovoltaic cells adjacent to a substrate, forming a plurality of conductors electrically connecting the plurality of photovoltaic cells to a lead foil, positioning the lead foil adjacent to the photovoltaic cells, and pulling a portion of lead foil up. The method can include forming a lead foil loop by pushing a pair of loop formation rollers together against the portion of lead foil from opposite direction. The first roller of the pair can have a circumferential indentation and the second roller can have a corresponding circumferential protuberance. The indentation can interlock with the protuberance to form a rib in the length of the lead foil loop when the rollers come together with a lead foil loop in between. The method can include positioning a back cover adjacent to the photovoltaic module surface. The back cover can have a hole and the lead foil loop can be positioned through the back cover hole.

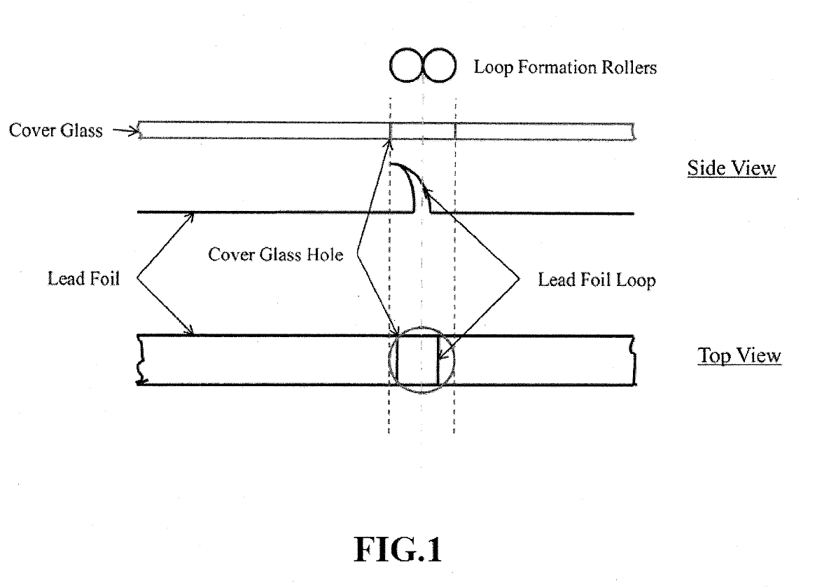

Referring to FIG. 1, the current process forms a loop by a set of rollers. However, the formed loop is not perpendicular to the surface of the plate and normally has a large feature. As shown in FIG. 1, the lead foil loop can have a “shark fin” shape that is not perpendicular to the module surface. It can be difficult to position a large feature lead foil through the back cover hole. The lead foil loop can be easily covered by the back cover, which can result in either rework or scrap.

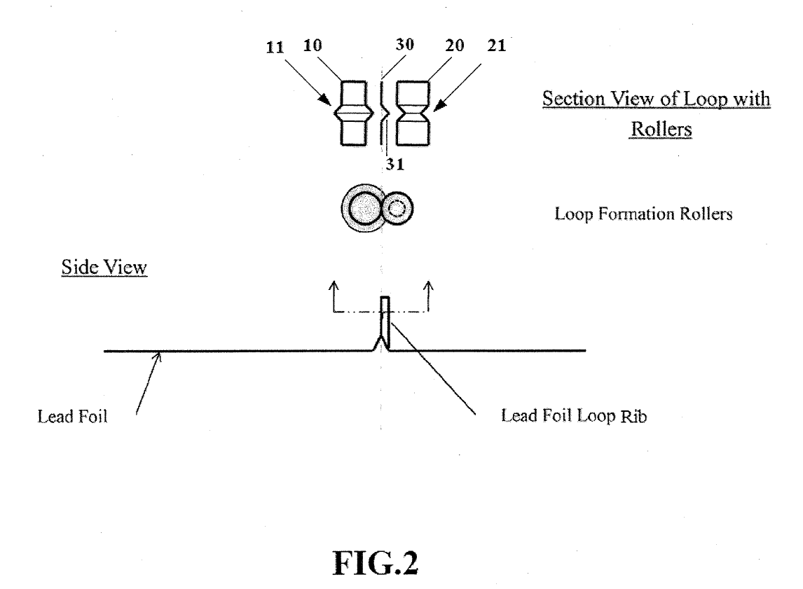

Referring to FIG. 2, a pair of loop formation roller (10 and 20) is developed: roller 20 can include circumferential indentation 21 and roller 10 can include corresponding circumferential protuberance 11. Indentation 20 can interlock with protuberance 11 to form rib 31 in the length of lead foil loop 30 when the rollers come together with a lead foil loop in between.

In some embodiments, the lead foil can include a tin plated copper foil. The lead foil can include an adhesive backing. In some embodiments, the loop formation rollers can include a plastic, metal, or any other suitable solid material. Indentation 20 can be a V-shape groove or any other suitable shape.

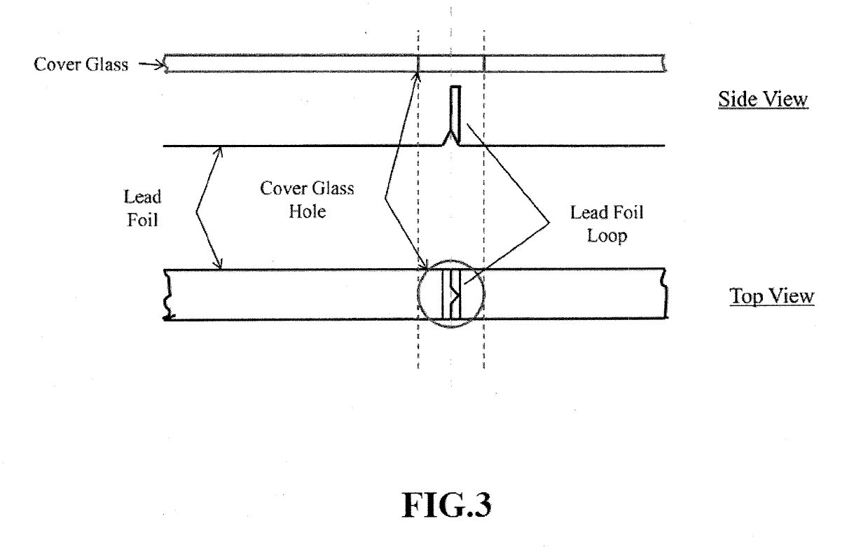

Referring to FIG. 3, a small rib in the lead foil loop can stiffen the loop so that the loop can stand straight and perpendicular to the surface of the module and back cover. Moreover, it has a smaller feature to make it easier to be positioned through the back cover hole.

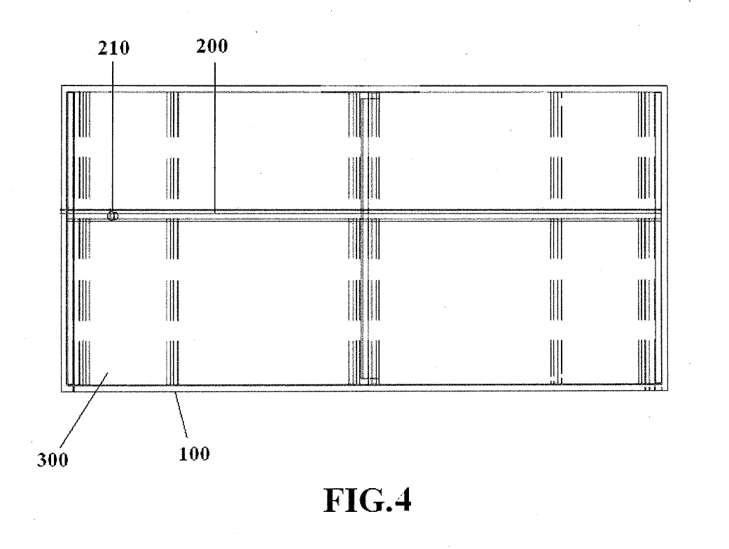

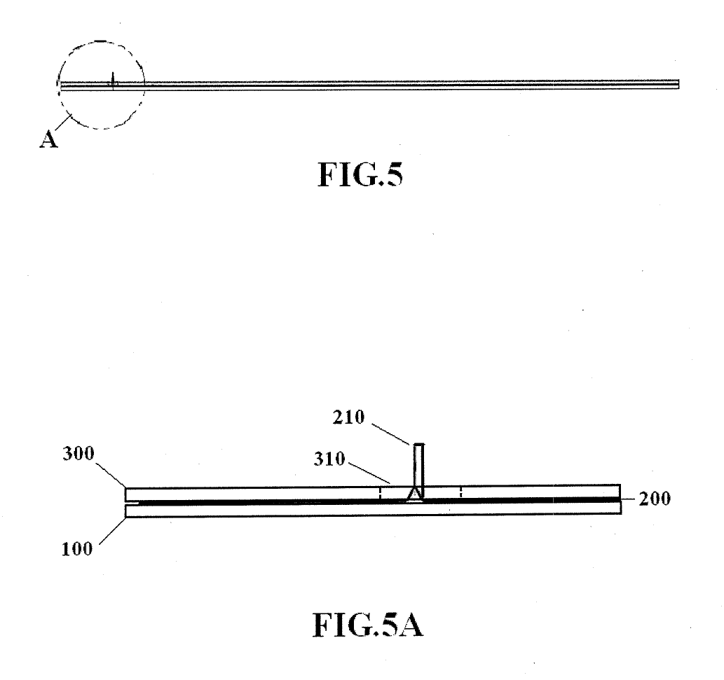

Referring to FIG. 4, lead foil 200 can attached to the surface of photovoltaic module 100. Back cover 300 can be attached to module 100. Referring to FIGS. 5 and 5A, with a rib, loop 210 can stand straight and perpendicular to the surface of module 100 and back cover 300. Loop 210 can be positioned through back cover hole 310.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

1-19. (canceled)

20. A method of forming lead foil loop for photovoltaic module manufacture comprising:
positioning a lead foil adjacent to a photovoltaic module surface;
pulling a portion of the lead foil up; and
forming a ribbed lead foil loop by interposing the portion of the lead foil between a first and second loop formation rollers, wherein the first loop formation roller comprises a circumferential indentation and the second loop formation roller comprises a corresponding circumferential protuberance configured to interlink with said circumferential indentation.

21. The method of claim 20, further comprising positioning a back cover adjacent to the photovoltaic module surface, wherein the back cover comprises a hole and the lead foil loop is positioned through the back cover hole.

22. The method of claim 20, wherein the lead foil comprises a tin plated copper foil.

23. The method of claim 20, wherein the lead foil comprises an adhesive backing.

24. The method of claim 20, wherein the ribbed lead foil loop is substantially perpendicular to said photovoltaic module surface.

25. The method of claim 20, wherein said portion of said lead foil comprises an end portion of said lead foil.

26. The method of claim 20, further comprising:
positioning a second lead foil adjacent to the photovoltaic surface;
pulling a portion of said second lead foil up; and
forming a second ribbed lead foil loop by interposing the second portion of the second lead foil between the first and second loop formation rollers.

27. The method of claim 26, wherein the first ribbed lead foil loop is positioned opposite the second ribbed lead foil loop.

28. The method of claim 26, further comprising attaching the first ribbed lead foil loop to the second ribbed lead foil loop.

29. A lead foil loop forming tool comprising:
a first loop formation roller, wherein the first loop formation roller comprises a circumferential indentation; and
a second loop formation roller, wherein the second loop formation roller comprises a circumferential protuberance, wherein the circumferential protuberance is configured to seat in circumferential indentation to form a rib in a lead foil loop when the first and second rollers come together with a lead foil loop there between.

30. The tool of claim 29, wherein at least one of the first or second loop formation rollers comprises a polymer.

31. The tool of claim 29, wherein at least one of the first or second loop formation rollers comprises a metal.

32. The tool of claim 29, wherein the first loop formation roller has a diameter between 0.3 cm and 5 cm.

33. The tool of claim 29, wherein the second loop formation roller has a diameter between 0.3 cm and 5 cm.

34. The tool of claim 29, wherein the circumferential protuberance comprises an o-ring positioned around the second roller.

35. The tool of claim 29, wherein the circumferential protuberance comprises a molded feature around the second roller.

36. The tool of claim 29, wherein the circumferential protuberance comprises a machined feature around the second roller.

37. The tool of claim 29, wherein the circumferential protuberance comprises a triangular-shaped cross section.

38. The tool of claim 29, wherein the circumferential indentation comprises a V-shaped cross section.

39. A method of manufacturing a photovoltaic module comprising:
forming a plurality of photovoltaic cells adjacent to a substrate;
forming a plurality of conductors electrically connecting the plurality of photovoltaic cells to a lead foil;
positioning the lead foil adjacent to the photovoltaic cells;
pulling up a portion of the lead foil; and
forming a ribbed lead foil loop by interposing the portion of the lead foil between a first and second loop formation rollers, wherein the first loop formation roller comprises a circumferential indentation and the second loop formation roller comprises a corresponding circumferential protuberance configured to interlink with said circumferential indentation.

40. The method of claim 39, further comprising positioning a back cover adjacent to the photovoltaic module surface, wherein the back cover comprises a hole and the lead foil loop is positioned through the back cover hole.

41. The method of claim 39, wherein the lead foil comprises a tin plated copper foil.

42. The method of claim 39, wherein the lead foil comprises an adhesive backing.

43. The method of claim 39, wherein the ribbed lead foil loop is formed substantially perpendicular to said photovoltaic module surface.

44. The method of claim 39, wherein said portion of said lead foil comprises an end portion of said lead foil.

45. The method of claim 39, further comprising:
positioning a second lead foil adjacent to the photovoltaic surface;
pulling a portion of said second lead foil up; and
forming a second ribbed lead foil loop by interposing the second portion of the second lead foil between the first and second loop formation rollers.

46. The method of claim 45, wherein the first ribbed lead foil loop is opposite the second ribbed lead foil loop.

47. The method of claim 45, further comprising attaching the first ribbed lead foil loop to the second ribbed lead foil loop.
